(19) United States
(12) Patent Application Publication
(10) Pub. No.: US 2015/0010026 A1
(43) Pub. Date: Jan. 8, 2015

(54) MEMS BASED SWEPT LASER SOURCE

(71) Applicant: Si-Ware Systems, Cairo (EG)

(72) Inventors: Bassam A. Saadany, Cairo (EG); Mohamed Sadek, Cairo (EG); Haitham Omran, Cairo (EG); Diaa Abdel Maged Khalil, Cairo (EG)

(73) Assignee: SI-WARE SYSTEMS, Cairo (EG)

(21) Appl. No.: 14/497,648

(22) Filed: Sep. 26, 2014

Related U.S. Application Data
(62) Division of application No. 13/528,328, filed on Jun. 20, 2012.
(60) Provisional application No. 61/498,959, filed on Jun. 20, 2011.

(51) Int. Cl. H01S 5/14

(52) U.S. Cl. CPC H01S 5/141
USPC 372/18

(57) ABSTRACT

A MEMS-based swept laser source is formed from two coupled cavities. The first cavity includes a first mirror and a fully reflective moveable minor and operates to tune the output wavelength of the laser. The second cavity is optically coupled to the first cavity and includes an active gain medium, the first mirror and a second mirror. The second cavity further has a length substantially greater than the first cavity such that there are multiple longitudinal modes of the second cavity within a transmission bandwidth of the first cavity output.

### CROSS REFERENCE TO RELATED PATENTS

The present U.S. Utility Patent Application claims priority pursuant to 35 U.S.C. §121 as a divisional of U.S. Utility Application No. 13/528,328, entitled “MEMS Based Swept Laser Source”, filed Jun. 20, 2012, which claims priority pursuant to 35 U.S.C. §119(e) to U.S. Provisional Application No. 61/498,959, entitled “MEMS Based Swept Laser Source”, filed Jun. 20, 2011, both of which are hereby incorporated herein by reference in their entirety and made part of the present U.S. Utility Patent Application for all purposes.

### BACKGROUND OF THE INVENTION

1. Technical Field of the Invention

The present invention relates in general to swept laser source designs, and in particular to the use of Micro Electro-Mechanical System (MEMS) technology in swept laser source design.

2. Description of Related Art

Swept laser sources are utilized in many applications, such as frequency domain optical coherence tomography (OCT), biomedical imaging, 3D data storage, multilayer coating, process control in pharmaceutical applications and in many sensing applications, such as glucose monitoring and optical biopsy. Recent advances in the fabrication of swept laser sources have enabled the production of swept laser sources with wide tuning ranges and miniaturized dimensions at lower costs. As a result, swept laser sources are now being commonly used in medical diagnostic applications, such as skin, teeth, bone and eye inspections and other medical inspection applications that require portability and mobility.

Portability of devices incorporating swept laser sources has been further enhanced by the use of MEMS (Micro-Electro-Mechanical Systems) technology to control wavelength sweeping in the swept laser source. MEMS technology can provide low cost, batch processing and the ability to integrate the source with other optical components, thus providing a completely integrated solution. Therefore, significant industrial and academic research has been oriented in the last decade towards the fabrication of swept laser sources using different MEMS topologies. For example, MEMS-based swept laser sources have been designed using closed loop configurations and continuous tuning single mode architectures.

However, existing MEMS-based swept laser sources suffer from the need to assemble many elements, resulting in complicated designs. Therefore, there is a need for an improved MEMS-based swept laser source design that provides a wide tuning range and fast wavelength sweeping.

### SUMMARY OF THE INVENTION

Embodiments of the present invention provide a swept laser source including a first cavity, a second cavity and a MEMS actuator. The first cavity is formed between a first minor and a fully reflective moveable mirror and operates to select at least one longitudinal mode of the first cavity as a first cavity output. The second cavity is optically coupled to the first cavity to receive the first cavity output. The second cavity including an active gain medium operating as an optical amplifier and is formed between the first minor and a second minor. The second cavity further has a length substantially greater than the first cavity such that there are multiple longitudinal modes of the second cavity within a transmission bandwidth of the first cavity output. The second cavity produces a laser output including at least one longitudinal mode of the second cavity that has a line width within the first cavity output. The MEMS actuator is coupled to the moveable minor to cause a displacement thereof to select the at least one longitudinal mode of the first cavity for the first cavity output, thereby tuning an output wavelength of the laser output. The first cavity, the second cavity and the MEMS actuator are fabricated on a silicon substrate.

In an exemplary embodiment, the first cavity operates as a notch rejection filter in the optical domain and as a selective notch reflection filter in the presence of the active gain medium in the second cavity to serve as a tunable element for the swept laser source. In another exemplary embodiment, the output wavelength of the laser output includes the longitudinal modes satisfying resonance conditions of the first cavity and the second cavity within a gain spectrum of the gain medium.

In a further embodiment, the second cavity further includes an optical fiber. In one configuration embodiment, the second minor may be formed on a first end of the optical fiber, while the first mirror is formed on a second end of the optical fiber or on an external side of the active gain medium, which is coupled to the second end of the optical fiber. In another configuration embodiment, the second mirror and the moveable minor may also form a MEMS Fabry Perot filter optically coupled to the optical fiber.

In another embodiment, the silicon substrate may further include a reflecting surface optically coupled to the first cavity to reflect the first cavity output towards the first minor. The reflecting surface may be a cylindrical or spherical reflecting surface.

In still another embodiment, the second mirror may also be a moveable minor that is coupled to an additional MEMS actuator. In this embodiment, the displacements of both the moveable minor and the second minor collectively tune the output wavelength of the laser output.

### BRIEF DESCRIPTION OF THE DRAWINGS

A more complete understanding of the present invention may be obtained by reference to the following detailed description when taken in conjunction with the accompanying drawings wherein:

FIG. 1 is a schematic block diagram of an exemplary Micro-Electro-Mechanical System (MEMS)-based swept laser source, in accordance with embodiments of the present invention;

FIG. 2 is a diagram illustrating longitudinal modes and corresponding output wavelengths of the MEMS-based swept laser source, in accordance with embodiments of the present invention;

FIG. 3 is a schematic block diagram illustrating an exemplary configuration of the MEMS-based swept laser source, in accordance with embodiments of the present invention;

FIG. 4 is a schematic block diagram illustrating another exemplary configuration of the MEMS-based swept laser source, in accordance with embodiments of the present invention;

FIG. 5 is a schematic block diagram illustrating yet another exemplary configuration of the MEMS-based swept laser source, in accordance with embodiments of the present invention; and

FIGS. 6A-6C are diagrams illustrating further configurations of the MEMS-based swept laser source, in accordance with embodiments of the present invention.

### DETAILED DESCRIPTION OF THE DRAWINGS

In accordance with embodiments of the present invention, a swept laser source is provided that includes two cavities; a large cavity and a small cavity. The large cavity includes an active gain medium and could be formed by an optical fiber, free space and/or silicon. The small cavity includes a MEMS movable mirror to tune the output wavelength. The MEMS-based swept laser source can be used, for example, in applications that require fast wavelength sweeping without restrictions on single mode operation. For example, the MEMS-based swept laser source may be incorporated into a swept source optical coherence tomography system, which can provide in-depth imaging in many fields, such as medical imaging, process and quality control, multilayer coating inspection, 3D data storage, and spectroscopic applications.

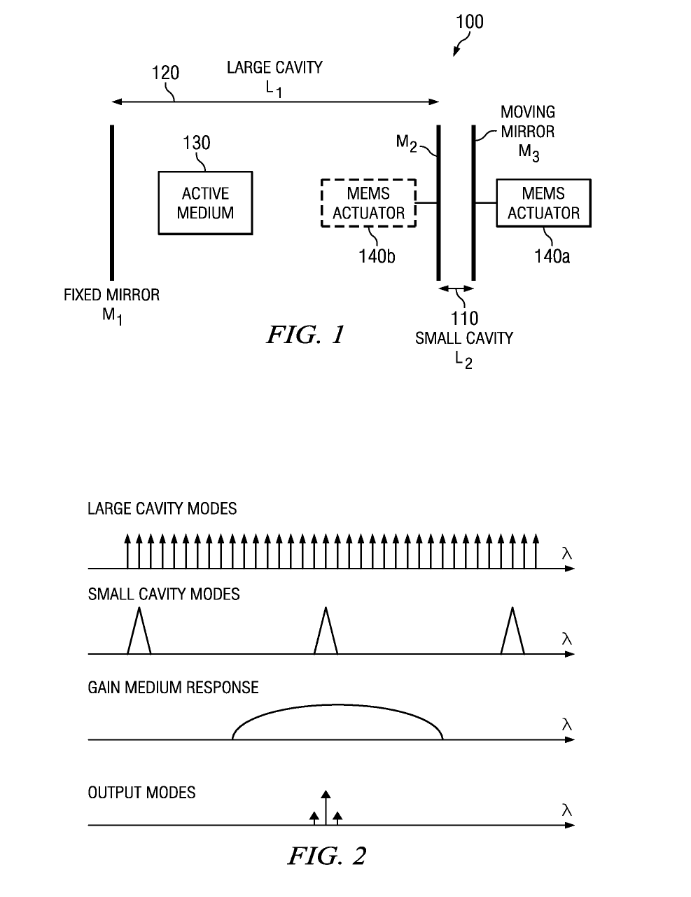

Referring now to FIG. 1, there is illustrated an exemplary MEMS-based swept laser source 100, in accordance with embodiments of the present invention. The MEMS-based swept laser source 100 includes a small cavity 110, a large cavity 120, an active gain medium 130, mirrors M₁, M₂ and M₃ and MEMS actuators 140a and 140b. The large cavity 120 includes the active gain medium 130 and is formed between mirrors M₁ and M₂, such that M₁ and M₂ define the ends of the large cavity 120. By way of example, but not limitation, the active gain medium 130 can include a semiconductor optical amplifier SOA, an Erbium Doped Fiber Amplifier EDFA, an optical fiber amplifier or any other type of optical amplifier. The small cavity 110 is formed between mirrors M₂ and M₃, such that M₂ and M₃ define the ends of the small cavity 110. In addition, minor M₃ defines one end of the swept laser source 100, while minor M₁ defines the other end of the swept laser source 100 and serves as an output for the swept laser source 100. In one embodiment, the small cavity 110 and the large cavity 120 are Fabry-Perot (F-P) cavities.

Mirrors M₁ and M₂ are partially transmissive and partially reflective, while M₃ is fully reflective (e.g. 97% reflective across the wavelengths of interest). For example, M₃ may be a metallic minor, while M₁ and M₂ may be dielectric mirrors or formed using Fiber Bragg Gratings (FBGs). Since M₃ is fully reflective, when used alone with M₂, the small cavity 110 operates as a notch rejection filter that suppresses its longitudinal modes (resonant wavelengths) from the small cavity output, and thus, prevents mode selectivity. However, by including the active gain medium within the large cavity 120, the combination of the small and large cavities 110 and 120 oscillates at the common longitudinal modes of the small/large cavities (as described in more detail below). As a result, the small cavity 110 is transformed into a selective notch reflection filter, reflecting selected wavelengths (longitudinal modes) towards the large cavity 120. Thus, the large cavity 120 is optically coupled to the small cavity 110 to receive an output thereof that includes one or more selected wavelengths (longitudinal modes of the small cavity 110).

The MEMS actuators 140a and 140b are electrostatic actuators, such as comb drive actuators, parallel plate actuators or other type of electrostatic actuators. The moveable minor M₃ is coupled to MEMS actuator 140a, such that motion of the MEMS actuator causes a displacement in the position of the moveable mirror M₃. Mirror M₂ may be coupled to optional MEMS actuator 140b in embodiments in which both M₂ and M₃ are moveable. As explained in more detail below, displacement of the moveable minor M₃ enables tuning of the output wavelength of the swept laser source 100. Likewise, in embodiments in which both M₂ and M₃ are moveable, the respective displacement of both M₂ and M₃ collectively tunes the output wavelength of the swept laser source 100.

The large cavity 120 has a length L₁, while the small cavity 110 has a length L₂, with L₁>>₂. For example, L₁ may be as long as several meters, while L₂ is on the order of a few microns. Since the longitudinal modes of a Fabry-Perot cavity are separated by an optical frequency interval given as Δν=C/2nL with C being the speed of light, n being the optical refractive index in the cavity and L being the length of the cavity, the Free Spectral Range (i.e., wavelength separation between the longitudinal modes) of the large cavity 120 is small, while the Free Spectral Range of the small cavity 110 is large, as illustrated in FIG. 2. Thus, the large cavity 120 has a large number of longitudinal modes within a wavelength range, and the small cavity 110 has a smaller number of longitudinal modes within the same wavelength range, as also illustrated in FIG. 2. For such a system of coupled cavities, the output wavelength of the swept laser source will include the longitudinal mode(s) that satisfy the resonance conditions for both the small cavity 110 and the large cavity 120 within the gain spectrum of the active gain medium 130. As a result, the modes of both cavities do not need to be aligned, which enables the swept laser source 100 to provide nearly continuous tuning.

By controlling the dimensions (e.g., L₂) of the small cavity 110 via displacement of the moveable minor M₃, the output wavelength of the swept laser source 100 can be tuned. For example, when minor M₃ is moved, the Free Spectral Range of the small cavity changes, thus changing the longitudinal modes of the small cavity on the wavelength axis (shown in FIG. 2). In embodiments in which both M₂ and M₃ are moveable, the longitudinal modes of both the small cavity 110 and the large cavity 120 move on the wavelength axis. However, there is always at least one longitudinal mode satisfying both cavity resonance conditions, since there are multiple longitudinal modes of the large cavity 120 within the Full Width Half Maximum (FWHM), or simply the transmission bandwidth, of each longitudinal mode of the small cavity 110.

In other words, the output of the small cavity 110 always includes a small number of longitudinal modes, each having a line width that contains at least one longitudinal mode of the large cavity 120. This is due to the fact that the number of longitudinal modes of the large cavity 120 is sufficiently large to enable at least one longitudinal mode of the large cavity 120 to lie entirely within the line width of the small cavity 110. This can be ensured when the separation between the longitudinal modes (Free Spectral Range) of the large cavity 120 is much smaller than the FWHM of the small cavity 110. Therefore, synchronization between the two cavities 110 and 120 is not needed, and as a result, wavelength tuning can be achieved with a more simple design than found in existing single mode tunable laser sources.

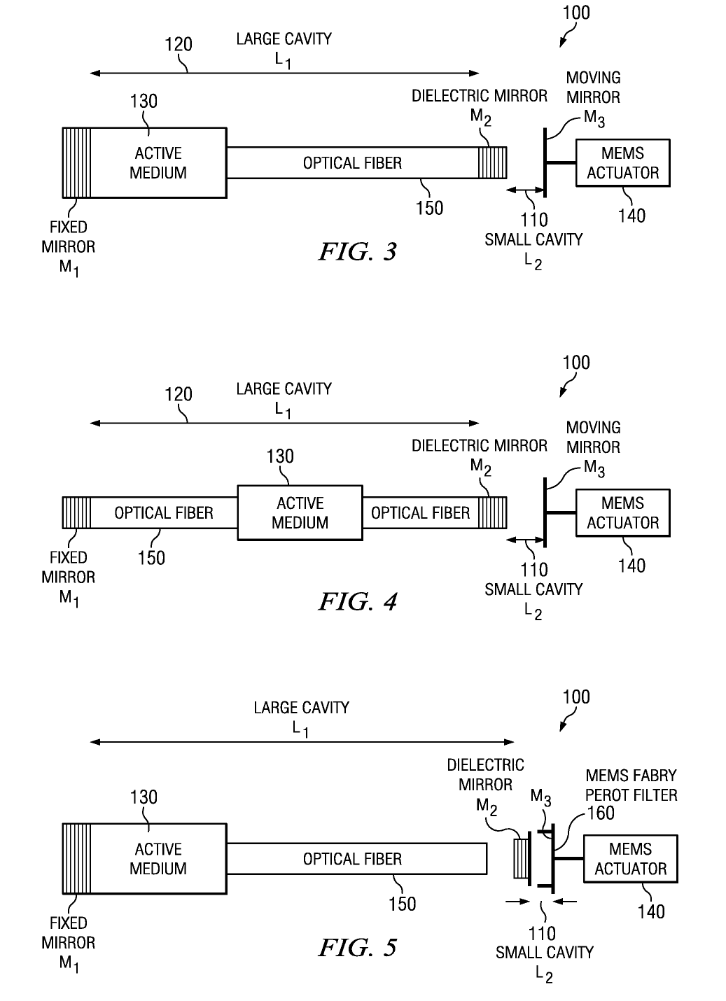

In one configuration of the MEMS-based swept laser source, as shown in FIG. 3, the large cavity 120 is formed using an optical fiber 150, while the small cavity 110 is formed using at least one moveable MEMS mirror M₃. The active gain medium 130 is coupled to one end of the optical amplifier 150, while the second mirror M₂ is coupled to the other end of the optical amplifier 150. Mirror M₁ is formed on an external side of the active gain medium 130. As such, the large cavity 120 is formed between mirror M₁ on one side of the active gain medium and minor M₂ at the end of the optical fiber 150. The small cavity is formed between minor M₂ and external moveable mirror M₃ acting as a selective reflection filter for determining a small line width to be amplified by the active gain medium 130. Mirror M₃ is moveable using a MEMS actuator 140 or any other type of actuator. In an exemplary embodiment, M₂ and M₃ are fixed on a MEMS alignment plate.

Mirrors M₁ and M₂ may be dielectric minors or metallic mirrors or any other type of minor that is both partially transmissive and partially reflective across the wavelength(s) of the swept laser source 100, while M₃ may be a metallic mirror or any other fully reflective minor across the wavelength(s) of the swept laser source 100. In one embodiment, the second minor M₂ is formed on the cleaved end of the optical fiber 150 using a dielectric coating or any other technique. In another embodiment, M₂ is formed using a Fiber Brag Grating FBG.

In another configuration of the swept laser source 100, as shown in FIG. 4, minor M₁ is coupled to one end of the optical fiber 150 and mirror M₂ is coupled to the other end of the optical fiber 150, while the active gain medium 130 is coupled between the ends of the optical fiber 150 to form the large cavity 120. As in FIG. 3, the small cavity 110 is formed between minor M₂ and moveable mirror M₃, which is coupled to MEMS actuator 140.

In yet another configuration, as shown in FIG. 5, the small cavity 110 is formed by a MEMS Fabry-Perot (F-P) filter 160 with mirror M₂ mounted on one side of the F-P filter 160 and moveable mirror M₃ mounted on the other side of the F-P filter 160. In an exemplary embodiment, moveable mirror M₃ is a DBR (Distributed Bragg Reflector) minor. The large cavity 120 is formed between mirror M₁, which is coupled to one end of the active gain medium 130, and minor M₂ of the MEMS F-P filter 160. The two cavities 110 and 120 are optically coupled via the optical fiber 150. In an exemplary embodiment, the end of the optical fiber 150 adjacent minor M₂ is AR (Anti-Reflection) coated. In another embodiment, mirror M₁ could be located at the end of the optical fiber 150 with the active gain medium 130 inside the optical fiber 150 or coupled between the fiber ends, as shown in FIG. 4.

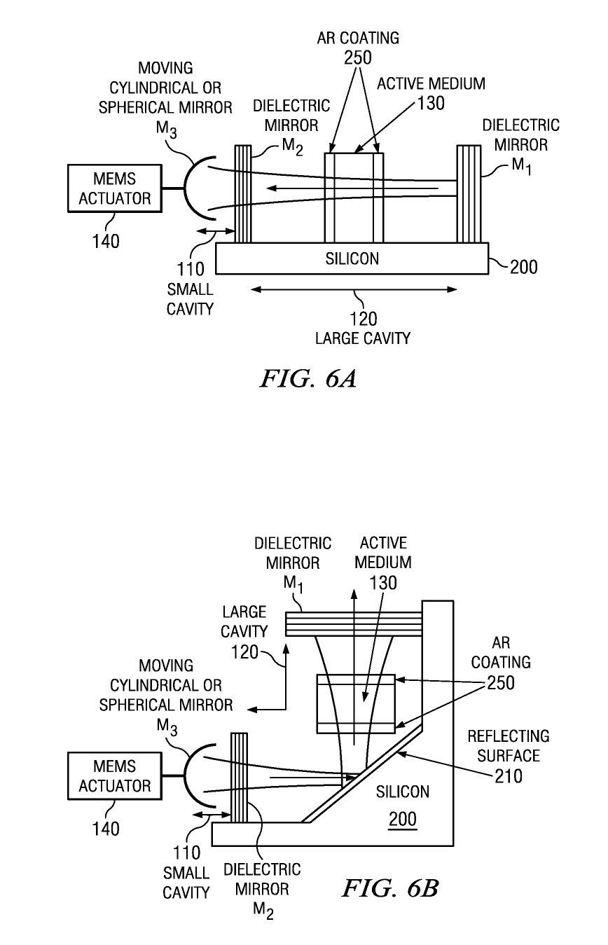

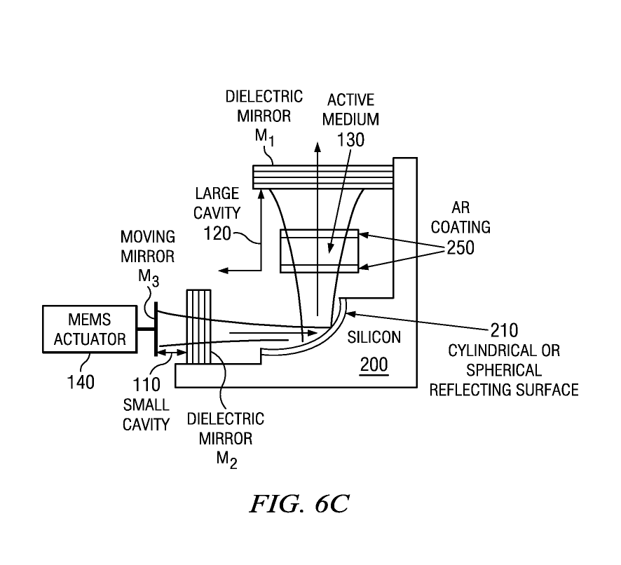

Turning now to FIGS. 6A-6C, in still another configuration, the two cavities 110 and 120 can be fabricated using MEMS technology, which allows the swept laser source 100 to have an integrated form. For example, fixed minors M₁ and M₂ and moveable minor M₃, along with the MEMS actuator 140 can be fabricated by a Deep Reactive-Ion Etching (DRIE) process and self-aligned by a lithography alignment process on a Silicon wafer/substrate, a GaAs wafer/substrate or any other semiconductor or dielectric wafer/substrate. Dielectric minors M₁ and M₂ may also be fabricated by selective deposition on the wafer. In addition, minors M₁-M₃ may be parallel to the wafer surface or perpendicular to the wafer surface.

In an exemplary embodiment, as shown in FIG. 6A, minors M₁, M₂ and M₃ and the active gain medium 130 are all fabricated on a silicon substrate 200 to be perpendicular to the surface thereof. Mirror M₃ may be a flat mirror or a curved mirror, the latter being illustrated in FIG. 6A. For example, mirror M₃ may be a cylindrical or spherical mirror to focus the beam(s) reflected therefrom and reduce losses. The active gain medium 130 may also be coated with an AR coating 250 to minimize the reflection loss in the large cavity 120 and avoid perturbing the resonance of the large cavity 120.

In another exemplary embodiment, as shown in FIG. 6B, the small cavity 110 is formed parallel to the plane of the substrate 200, and the large cavity is formed substantially orthogonal to the direction of the small cavity 110. For this configuration, substrate 200 includes an angled reflecting surface 210 to direct the output of the small cavity 110 towards the active gain medium 130 and increase the length of the large cavity 120 within a small surface area of the substrate 200. This redirection can also be repeated several times to increase the length of the large cavity 120, while maintaining a small footprint on the wafer 200.

In yet another exemplary embodiment, as shown in FIG. 6C, moveable mirror M₃ is flat, while the reflecting surface 210 of the substrate 200 is curved (e.g., cylindrical or spherical reflecting surface) to perform the focusing function. In other embodiments, a separate focusing element (e.g., a conventional lens, a Fresnel lens, or a curved mirror) can be fabricated from the wafer material itself or any other material and may also be coated with AR coating to minimize the diffraction loss in the cavities 110 and 120.

In still another embodiment, an additional wafer can be placed on top of the substrate 200 with the active medium 130 and mirror M1 being integrated on a top surface thereof such that the output of the small cavity is directed through the top wafer towards the active gain medium 130 and mirror M₂. In this embodiment, the two wafers could be bonded together to form a completely integrated swept laser source 100.

In any of the above configurations, the small cavity 110 may be replaced by a MEMS grating acting as a filter. In this case, either the grating rotates to change the selected wavelength or the grating has a fixed position and another rotating mirror is used with it for the wavelength selection.

As will be recognized by those skilled in the art, the innovative concepts described in the present application can be modified and varied over a wide range of applications. Accordingly, the scope of patents subject matter should not be limited to any of the specific exemplary teachings discussed, but is instead defined by the following claims.

We claim:

1. A swept laser source, comprising:
a first cavity formed between a first mirror and a moveable mirror that is fully reflective, the first cavity being operable to select at least one longitudinal mode of the first cavity as a first cavity output;
a second cavity optically coupled to the first cavity to receive the first cavity output, the second cavity including an active gain medium operating as an optical amplifier and being formed between the first minor and a second minor, the second cavity having a length substantially greater than the first cavity such that there are multiple longitudinal modes of the second cavity within a transmission bandwidth of the first cavity output, the second cavity producing a laser output including at least one longitudinal mode of the second cavity that has a line width within the first cavity output; and
a Micro-Electro-Mechanical Systems (MEMS) actuator coupled to the moveable minor to cause a displacement thereof to select the at least one longitudinal mode of the first cavity for the first cavity output, thereby tuning an output wavelength of the laser output;
wherein the first cavity, the second cavity and the MEMS actuator are fabricated on a silicon substrate.

2. The swept laser source of claim 1, wherein the first cavity operates as a notch rejection filter in the optical domain and as a selective notch reflection filter in the presence of the active gain medium in the second cavity to serve as a tunable element for the swept laser source.

3. The swept laser source of claim 1, wherein the output wavelength of the laser output includes the longitudinal modes satisfying resonance conditions of the first cavity and the second cavity within a gain spectrum of the gain medium.

4. The swept laser source of claim 1, wherein the active gain medium includes a semiconductor optical amplifier.

5. The swept laser source of claim 1, wherein the active gain medium includes an erbium doped fiber amplifier.

6. The swept laser source of claim 1, wherein the first minor and the second minor are both partially transmissive and partially reflective.

7. The swept laser source of claim 1, wherein the second cavity further includes an optical fiber.

8. The swept laser source of claim 7, wherein the first mirror is formed on a first end of the optical fiber.

9. The swept laser source of claim 8, wherein the active gain medium is coupled to a second end of the optical fiber and the second mirror is formed on an external side of the active gain medium.

10. The swept laser source of claim 8, wherein the active gain medium is within the optical fiber and the second minor is formed on a second end of the optical fiber.

11. The swept laser source of claim 7, wherein the first mirror and the moveable minor form a MEMS Fabry Perot filter optically coupled to the optical fiber.

12. The swept laser source of claim 1, wherein the first mirror is a second moveable minor.

13. The swept laser source of claim 12, further comprising:
an additional MEMS actuator coupled to the second moveable minor to cause a displacement thereof, the displacement of the moveable minor and the second moveable minor collectively tuning the output wavelength of the laser output.

14. The swept laser source of claim 1, wherein the silicon substrate includes a reflecting surface optically coupled to the first cavity to reflect the first cavity output towards the second mirror.

15. The swept laser source of claim 14, wherein the reflecting surface is a cylindrical or spherical reflecting surface.

16. The swept laser source of claim 1, wherein the first minor and the second minor are each selected from the group consisting of: dielectric minors or Fiber Bragg Gratings.

17. The swept laser source of claim 1, further comprising:
an anti-reflection coating on at least one side of the active gain medium.

18. The swept laser source of claim 1, wherein the moveable mirror is a metallic mirror.

19. The swept laser source of claim 1, wherein the moveable mirror is a cylindrical or spherical mirror.
